(19) United States
(12) Patent Application Publication
(10) Pub. No.: US 2014/0196664 A1
(43) Pub. Date: Jul. 17, 2014

(54) SYSTEM AND METHOD FOR TUNGSTEN HEXAFLUORIDE RECOVERY AND REUSE

(71) Applicant: AIR PRODUCTS AND CHEMICALS, INC., Allentown, PA (US)

(72) Inventors: Andrew David Johnson, Doylestown, PA (US); Rajiv Krishan Agarwal, Malvern, PA (US); Heui-Bok Ahn, Gyeonggi-Do (KR); William Jack Casteel, JR., Emmaus, PA (US); Eugene Joseph Karwacki, JR., Orefield, PA (US); John Francis Lehmann, Bethlehem, PA (US); David Charles Winchester, Walnutport, PA (US)

(73) Assignee: AIR PRODUCTS AND CHEMICALS, INC., Allentown, PA (US)

(21) Appl. No.: 14/149,318

(22) Filed: Jan. 7, 2014

Related U.S. Application Data
(60) Provisional application No. 61/753,635, filed on Jan. 17, 2013.

(51) Int. Cl. C23C 16/30; H01L 21/02; C23C 16/44

(52) U.S. Cl. CPC C23C 16/30; C23C 16/4412; H01L 21/0262
USPC 118/712

(57) ABSTRACT

Condensable materials, such as but not limited to tungsten fluoride (WF₆), can be used deposit films in a chemical vapor deposition (CVD) process. Described herein are methods to collect and reuse the condensable materials that are unreacted in the production process rather than treat these materials as waste. In one embodiment, when a condensable material, such as gaseous WF₆, is not supplied to the CVD reactor, it is redirected to a recovery cabinet for capture.

### CROSS-REFERENCE TO RELATED APPLICATIONS

This application claims benefit of U.S. Provisional Application No. 61/753,635, filed Jan. 17, 2013. The disclosure of this provisional application is hereby incorporated by reference in its entirety.

### BACKGROUND OF THE INVENTION

Described herein are systems and methods for recovery of semiconductor manufacturing materials, such as for example, tungsten hexafluoride (WF₆). Also described herein are systems and methods that recover and then reuse the semiconductor manufacturing materials for semiconductor manufacturing.

Tungten hexafluoride (WF₆) is a condensable material that is used in the manufacture of semiconductor devices. WF₆ is manufactured for use in semiconductor manufacturing processes and is typically used as a reactant in the chemical vapor deposition (CVD) for forming tungsten films. A common way to synthesize WF₆ is by the highly-exothermic reaction of elemental fluorine (F₂) and tungsten metal as shown in reaction (1) below:

W(s)+3F₂=WF₆(g)(ΔH°=−418 kcal/mol) Reaction (1)

During CVD processing, the WF₆ is not efficiently utilized. Unreacted WF₆ is directed to the reactor exhaust and disposed as waste. Typically, WF₆ is hydrolyzed using a wet scrubber, generating waste-water containing aqueous hydrofluoric acid (HF (aq)) and tungsten oxides (WOₓ). This waste-water must then be treated at a waste-water treatment facility before it can be discharged.

Accordingly, there is a need to provide a method, system, apparatus or combinations thereof for capturing the WF₆ and other condensable materials to be reused and/or recycled in a production process. There is a need in the art to reduce the costs of condensable materials such as WF₆ which are delivered to a production tool in, for example, a CVD process. There is a further need in the art to reduce the waste of condensable materials that are used in the production process.

### BRIEF SUMMARY OF THE INVENTION

The method, system, and apparatus described herein fulfill at least one of the needs in the art. In one aspect, there is provided an apparatus for capture and recovery of a condensable material from a chemical process reactor that uses the condensable material, comprising;

(a) a chemical process reactor provided with one or more lines for introducing the condensable material in electrical communication with a process controller;

(b) an effluent line from the chemical process reactor capable of removing unreacted condensable material introduced into the chemical process reactor;

(c) optionally a check valve in the effluent line allowing removal of the unreacted condensable material from the chemical process reactor and preventing any substantial flow of effluent to the chemical process reactor having a set cracking pressure;

(d) a recovery line having a connection to chemical process reactor, or the effluent line, upstream of the optional check valve, capable of removing the unreacted condensable material from the chemical process reactor or effluent line and sending it to a recovery vessel;

(e) an automatic valve in the recovery line having a signal connection to a process controller;

(f) a process controller; and,

(g) the recovery vessel further comprising a cooling jacket in electrical communication with the process controller and capable of housing the unreacted condensable material.

In another aspect, there is provided a system for the capture and recovery of a condensable material from a chemical process reactor that uses the condensable material, comprising;

a chemical process reactor provided with one or more lines for introducing the condensable material in electrical communication with a process controller;

an effluent line from the chemical process reactor capable of removing unreacted condensable material introduced into the chemical process reactor;

optionally, a check valve in the effluent line allowing removal of the unreacted condensable material from the chemical process reactor and preventing any substantial flow of effluent to the chemical process reactor having a set cracking pressure;

a recovery line having a connection to the chemical process reactor, or effluent line, upstream of the optional check valve, capable of removing the unreacted condensable material from the chemical process reactor or effluent line and sending it to a recovery vessel;

an automatic valve in the recovery line having a signal connection to a process controller;

a process controller; and,

the recovery vessel further comprising a cooling jacket in electrical communication with the process controller and capable of housing the unreacted condensable material.

### BRIEF DESCRIPTION OF SEVERAL VIEWS OF THE DRAWINGS

FIG. 1 provides a process flow-diagram of one embodiment for recovering a condensable material such as WF₆ for future re-use.

FIG. 2 provides the liquid-vapor phase diagram for WF₆. The solid line represents the phase boundary between condensed WF₆ and gaseous WF₆. For conditions above the solid line, WF₆ exists as a liquid or solid. For conditions under the solid line, WF₆ exists as a gas.

FIG. 3 provides an example of one embodiment of the equipment and system used to capture and recover a condensable material such as WF₆.

### DETAILED DESCRIPTION OF THE INVENTION

Material recovery provides an opportunity to reduce the cost and amount of waste generated by semiconductor manufacturing processes. Effluents from semiconductor processes, such as WF₆ or other condensable materials, may include valuable materials that can be recovered for reuse rather than being treated as waste. Material recovery improves the utilization efficiency of, and reduces the amount of waste generated by, the manufacturing process. While the method, system and/or apparatus described herein is used for capturing and reusing tungsten hexafluoride (WF), it is believed that these methods, systems, and/or apparatus, can be extended to other condensable materials.

Described herein is a means to recover desirable condensable materials, such as but not limited to WF₆, in yields that minimize production waste and allow the condensable materials to be captured and stored for re-use in the manufacturing process. WF₆ delivered to the production tool, but not utilized in the CVD of tungsten films, is directed to the reactor exhaust and is disposed of as waste. The method, system, and system described herein allows for the production waste or unreacted W₆ to be captured into a storage vessel such as a cylinder and then reused for future production. Several methods of capture are contemplated: condensation, complexation, and combinations thereof. These capture methods store the WF₆ in a condensed phase in a vessel, in a support, or a combination thereof. The WF₆ can subsequently be reused by heating the vessel and/or a support within the vessel and vaporizing the WF₆. Exemplary yields obtainable for the WF₆ or condensable material for reuse using the method described include one or more of the following endpoints: 10 vol % or greater, 20 vol % or greater, 30 vol % or greater, 40 vol % or greater, 50 vol % or greater, 55 vol % or greater, 60 volume % or greater, 65 vol % or greater, 70 vol % or greater, 75 vol % or greater, 80 vol % or greater, or 90 vol % or greater based on the gross material supply. Also described herein is an apparatus and system that efficiently captures the WF₆ for reuse in production.

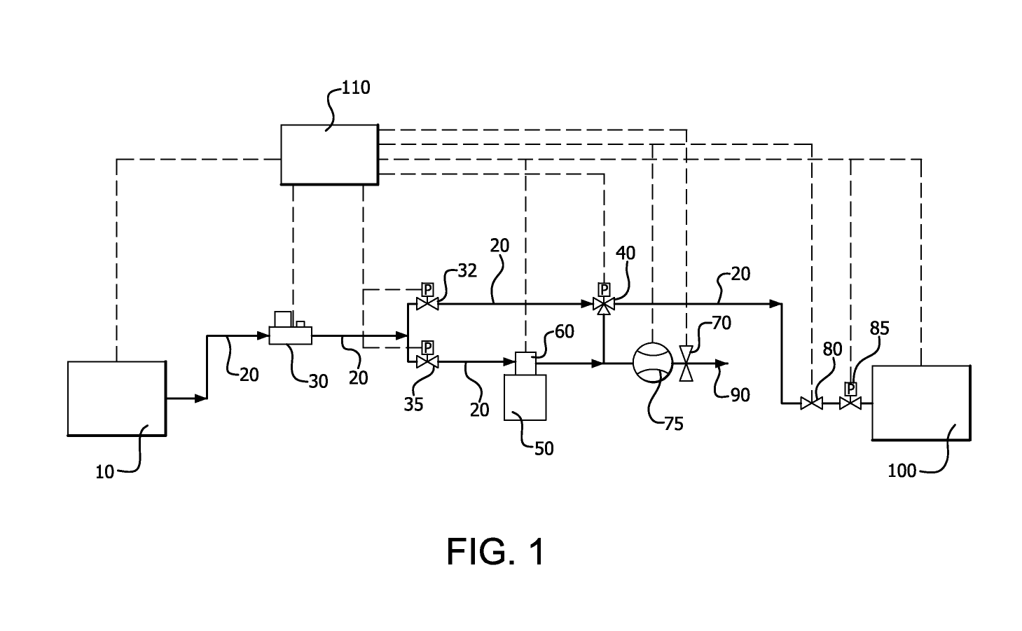

FIG. 1 provides one embodiment of the method described herein. As FIG. 1 illustrates, WF₆ is provided as a gas from supply cabinet 10 which may further include a storage vessel such as a storage cylinder (not shown in FIG. 1) to contain the WF₆. The materials of construction of the storage cylinder (not shown), recovery cylinder (not shown), and process lines 20 should be preferably meet one or more of the following parameters: be corrosion-resistant and withstand process temperatures up to approximately 111° C. or 232° F. With regard to being corrosion-resistant, in certain applications, the end-user may passivate one or more portions of process line 20 by introducting a fluorine gas, such as elemental fluorine (F₂), to remove any adsorbed moisture or hydroxides which can react with WF₆ and form undesirable by-products such as HF. Suitable materials for process line 20 and the storage and/or recovery cylinders include stainless steel. In certain embodiments, the material for the process line may be comprised of nickel, nickel alloys, or nickel plated stainless steel. Supply cabinet 10 is in fluid communication with production tool 50 which further comprises a deposition reactor 60 to which the WF₆ is supplied to in gaseous form via process line 20 via mass flow controller 30 which can provide uninterrupted supply of WF₆ to the production tool 50 and deposition reactor 60. Process tool 50 assists in the performance of various steps of semiconductor fabrication, including deposition of a tungsten film on a surface of a semiconductor substrate by CVD, in deposition reactor 60. The process tool 50 may comprise one or more deposition reactors 60. The substrate may be comprised of one or more semiconductor wafers such as a “boat” or carrier of a series of wafers stacked on their edge. The substrate can be introduced into the reactor 60 through a load lock from a load chamber (not shown) in process tool 50. As shown in FIG. 1, mass flow controller 30 controls the flow of WF₆ delivered to deposition reactor 60 to a certain flow rate such as, for example, 300 standard cubic centimeters (sccm) as shown. However, the flow rate and other attributes of flow of WF₆ to production tool 50 and deposition reactor 60 can be controlled via the end user. Whenever WF₆(g) is not supplied to the deposition reactor 60, it can be re-directed to a recovery cabinet 100 for capture in a storage vessel such as a recovery cylinder (not shown in FIG. 1) via two-way valve 32, three-way valve 40, two-way valve 80, and two-way valve 85 thereby by-passing process tool 50 and deposition reactor 60.

During processing, WF₆(g) is supplied to deposition reactor 60. Any unreacted WF₆ can be directed via process line 20 to automatic valve 40, through two valves 80 and 85 and collected in one or more storage vessels (not shown) in recovery cabinet 100. Alternatively, un-reacted WF₆ or any effluent gas such as passivation or purge gas can be directed to check-valve 70 after vacuum pump 75 and is directed to the production facility exhaust 90 for the purpose of purging the line. Effluent that passes through the check valve 70 is sent into an abatement, scrubbing and production facility exhaust system (not shown) through fab exhaust line 90 to decompose, burn or sorb toxic, hazardous, corrosive or global warming gases.

FIG. 1 further shows central processing unit CPU or process controller 110 which is in electrical communication as shown by the dashed line in FIG. 1 with any one or more of the elements of the system shown in FIG. 1: WF₆ supply cabinet 10, mass flow controller 30, valves 35, 32, 40, 70, 80, and/or 85, vacuum pump 75, process tool 50, deposition reactor 60, and/or WF₆ recovery cabinet 100. In one embodiment, the process controller 110 can monitor the process tool 50 and deposition tool 60 and adjust its temperature, control plasma conditions and maintain pressures to set parameters. Process controller 110 can be monitored and/or controlled by electrical communication with mass flow controller 30, such that a certain flow rate and sequence of WF₆ is introduced into the reactor 60.

Process controller 110 can further control any one or more of valves 35, 32, 40, 70, 80, and/or 85 via electrical communication. Unreacted WF₆ from the reactor 60 can be drawn away from process tool 50 into an exhaust effluent vacuum pump 75, through check-valve 70 and to the fab exhaust line 90. In one particular embodiment, check-valve 70 is set with a minimum cracking pressure, which represents the pressure at which it will open to allow flow and below which it will close to prevent backflow toward the reactor 60.

As previously mentioned, WF₆ recovery cabinet 10 in FIG. 1 can be isolated from the process tool 50 and deposition reactor 60 by closing valve 35, 32, and 40. This timing, sequence and delayed, phased time to discretely remove and recover the WF₆ from its continuous flow is monitored and/or controlled by the process controller 110 through one or more signal connections (not shown) to the automatic valve 85.

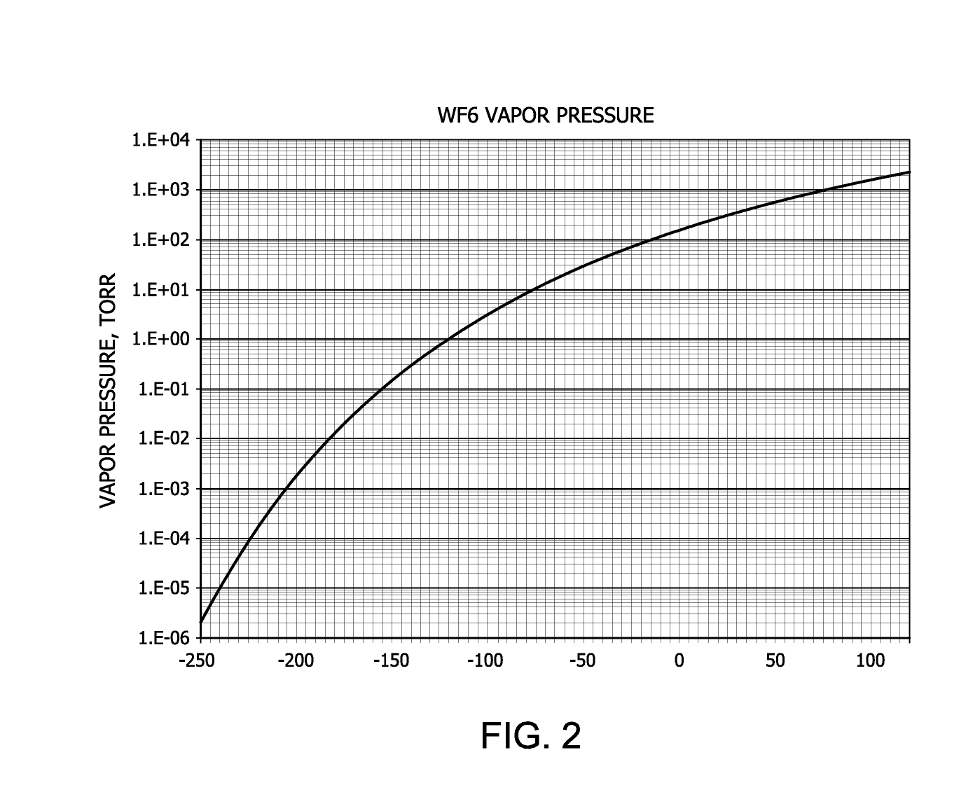

As previously mentioned, the method, system and apparatus described herein may use one of several methods for capture of a condensable material: condensation, complexation, or a combination thereof. In one embodiment, the condensable material such as WF₆ is captured via condensation. Referring to the phase diagram in FIG. 2, condensation involves collecting WF₆ in a storage vessel under temperature and vapor pressure conditions where the phase diagram shows WF₆ to be a liquid or solid which is generally the area above the solid line in FIG. 2 (e.g., relatively higher vapor pressure and lower temperature). Capture by condensation is achieved by operating the capture vessel under temperature conditions such that the condensable material is a liquid or solid as indicated by its phase-diagram. In one particular embodiment of the method and system described herein, the temperature of the recovery cylinder or collection vessel is measured using a temperature sensor or thermocouple. In this or other embodiments, the pressure of recovery cylinder or the collection vessel is measured by a pressure transducer. For WF₆, at a pressure of 1000 torr, the temperature must be lower than 21° C. or 70° F. Preferably, the conditions of temperature and pressure are 13° C. or 55° F. and 700 torr, respectively. In this way, the gaseous WF₆(g) from the process can be recovered for reuse by heating the recovery cylinder or collection vessel to increase the WF₆ vapor pressure. For example, if the collection vessel is warmed to room temperature (21° C. or 70° F.), the vapor pressure is 1000 torr. Under these conditions, the recovered WF₆(g) can be delivered to the process tool or deposition reactor.

In an alternative embodiment, capture of the condensable material by complexation is achieved by filling the recovery cylinder or collection vessel with a support such as, without limitation, activated potassium fluoride (KF). An activated KF support could capture the gaseous WF₆(g) material as a mixture of solid KWF₇(s) and K₂WF₈(s). The gaseous WF₆(g) is recovered for reuse by heating the KF support to approximately 100° C. or 212° F. to release gas phase WF₆(g). In a further embodiment, a zirconium or alumina support could be used to activate the adsorption by providing a higher surface area for complexation. In yet another embodiment, a finely-divided powder could be used. In the foregoing embodiments, the captured tungsten containing solid or support comprising same can be heated under certain conditions such as temperature and/or pressure to convert the solid or support comprising same back to WF₆(g).

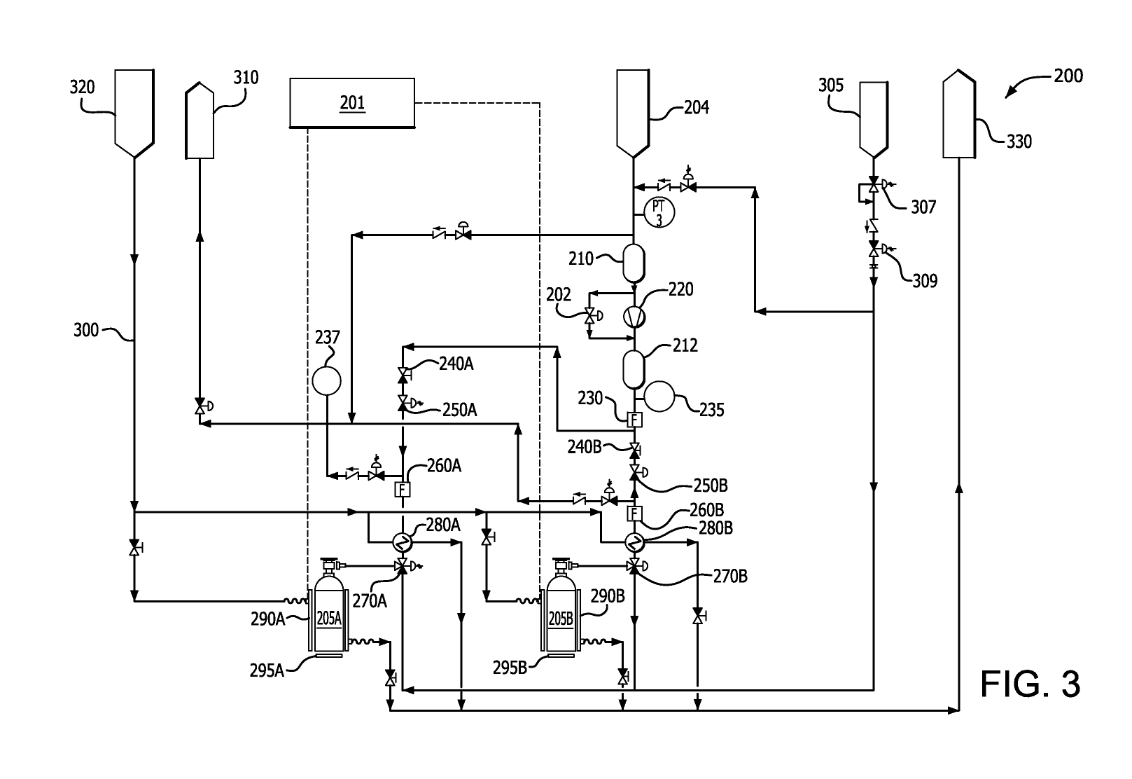

FIG. 3 provides an embodiment of a system 200 for capturing and recovering WF₆. The unreacted WF₆ effluent from the process is introduced via feed line 204 through buffer tank 210 and compressed using compressor 220. The WF₆(g) partial pressure is measured using pressure transducer 235. Back-pressure regulator 202 is optional. The gas phase WF₆ is transported to the storage vessel 205A through filter 230, shutoff valves 240A, 250A, filter 260A and valve 270A. There is a redundant back-up system wherein the WF₆(g) can be re-directed to storage vessel 205B through filter 230, and then through shutoff valves 240B and 250B, filter 260B and valve 270B. An optional condenser 280A or 280B (depending upon the side) can cool the WF₆ gas before the WF₆ is condensed in a vessel 205A that is cooled with a cooling jacket 290A. Conditions of about 13° C. or 55° F. temperature and 700 torr pressure are preferred since this can be achieved using chilled water line in fluid communication with the cooling water supply via process line 300 and a diaphragm compressor (not shown). A scale or level sensor 295A or 295B indicates when the vessel 205A or 205B, respectively, is full and needs to be replaced with another vessel.

Central processing unit or process controller 201 is in electrical communication with any one or more of the elements provided in FIG. 3. For example, in the embodiment shown in FIG. 3, process controller 201 can be in electrical communication with one or more sensors associated with storage vessels 205A and/or 205B to monitor its temperature, pressure, capacity or other relevant parameters. However, process controller 201 can be in electrical communication with additional elements of system 200 which are not shown in the Figure.

In another embodiment of the system in FIG. 3, an additional compressor, such as optional compressor 220, may be needed. In this system, vessel 205A and/or 205B can be cooled to about −10° C. or 14° F. or lower. WF₆ is a solid at about —10° C. or 14° F. with a vapor pressure of 255 torr. In the capture mode, the recovery WF₆ is directed to vessel 205A or 205B without the compressor. In this embodiment, the feed line pressure must be higher than 255 torr at this stage. Once vessel 205A or 205B is full as indicated by scale 295A or 295B, it can be replaced by another vessel. After its filled, vessel 205A or 205B can be warmed up to room temperature to provide a source of pure WF₆.

Cylinder change and automatic cross-over techniques normally practiced enable continuous recovery operations. FIG. 3 illustrates an embodiment of the system that comprises a 2 cylinder cabinet for capture of WF₆. When vessel 205A is full, the cylinder valve 250A is closed and WF₆ directed to vessel 205B. The unreacted WF₆ effluent is introduced through buffer tank 210 from feed line 200 and compressed using compressor 220. An additional buffer tank 212 is added to the line to take out any pressure pulsation caused by compressor 220. The W F₆(g) partial pressure is measured using transducer 235. The gas phase WF₆ is transported to the storage vessel 205B through filter 230, shutoff valves 240B, 250B, filter 260B, and valve 270B. An optional condenser 280B can cool the WF₆ gas before the WF₆ is condensed in a vessel 205B that is cooled with a cooling jacket 290B. Conditions of about 13° C. or 55° F. temperature and 700 torr pressure are preferred since this can be achieved using chilled water and a diaphragm compressor. Similar to the “A” side, scale 295B indicates when the vessel is full and needs to be replaced with another vessel. Cylinder change and automatic cross-over techniques normally practiced enable continuous recovery operations.

FIG. 3 also shows process lines for various utilities (e.g., vacuum 310, purge line 305 such as N₂) which may be optionally needed, for example, for cylinder change operations normally practiced in gas delivery to process reactors. Cooling water is supplied to condensers 280A and 280B and cooling jackets 290A and 290B through cooling water input 320 through line 300 and cooling water return 330.

Once the collection vessels 205A, 205B, or combinations thereof are full, they are removed from the recovery cabinet system using purge and evacuation techniques normally practiced to prevent corrosion and operator exposure. These techniques may be automated using a process controller 210 in electrical communication with one or more automatic valves within the same system. The collection vessels 205A and/or 205B can then be moved to a supply cabinet which is used to supply WF₆ to the process reactor such as, without limitation, WF₆ supply cabinet 10 in FIG. 1.

In the systems and embodiments described herein, it is preferable that the surfaces in contact with liquid WF₆ should ideally be nickel or nickel-plated to prevent its contamination with metals. In this regard, the chromium component of stainless steel alloys may volatize as chromium fluorides. Nickel is more resistant to corrosion than stainless steel. In one embodiment of the system of FIG. 3, collection vessels 205A and 205B can be made of nickel or be nickel-plated. In these or other embodiments, the captured WF₆ remains uncontaminated and can then be reused in the original manufacturing process without any need for purification.

In one embodiment, the WF₆ recovery cabinet and supply cabinet can be combined in one system. In this embodiment, an integrated supply and recovery cabinet enables recovery and reuse without the need for cylinder change necessary for a stand alone recover cabinet. Gas phase WF₆ can be supplied from one vessel in the cabinet and recovered as a liquid in the other vessel. This system may further comprise a third cylinder to allow continual operation. In this or other systems, a central recovery cabinet allows recovery of WF₆ from multiple process reactors. The size of collection vessels in the recovery cabinet would be chosen based upon the number of process reactors and their WF₆ usage.

While the embodiments shown herein are described using WF₆ as the condensable material, it is anticipated that other condensable material that can be recovered and recycled could be, for example, a deposition precursor such as an organosilane or an organometallic material. In one embodiment, the chemical process reactor is a deposition chamber such as a chemical vapor deposition reactor or an atomic layer deposition reactor. Excess deposition precursor materials such as an organosilane or an organometallic material can be recovered from the deposition chamber and captured for reuse using the system and method described herein. Exemplary organosilane materials include, without limitation, disilane, tetrasilane, pentasilane, di-isopropylaminosilane, or combinations thereof. Exemplary organometallic materials include any materials having an organic component and one or more of the following metals Ru, Ti, Zr, Hf, Cu, Al, Ta, Zn, W, Nb, Mo, Mn, Ce, Gd, Sn, Co, Mg, Sr, La, and combinations thereof.

1. An apparatus for a recovery of a condensable material from a chemical process reactor that uses the condensable material, comprising;
(a) a chemical process reactor provided with one or more lines for introducing the condensable material in electrical communication with a process controller;
(b) an effluent line from the chemical process reactor capable of removing an unreacted condensable material introduced into the chemical process reactor;
(c) a recovery line having a connection to the effluent line wherein the recover line is upstream of the check valve and wherein the recovery line and sends the unreacted condensable material from the effluent line and to a recovery vessel;
(d) an automatic valve in the recovery line having a signal connection to the process controller;
(e) a process controller; and,
(f) the recovery vessel further comprising a cooling jacket in electrical communication with the process controller and capable of housing the unreacted condensable material.

2. The apparatus of claim 1 wherein the condensable material comprises WF₆.

3. The apparatus of claim 1 wherein the condensable material comprises an organosilane.

4. The apparatus of claim 1 wherein the condensable materials comprises an organometallic.

5. The apparatus of claim 1 wherein the recovery vessel which collects the condensable material further comprises KF as a complexing agent.

6. The apparatus of claim 1 wherein the recovery vessel comprises nickel.

7. The apparatus of claim 1 wherein the recovery vessel is comprised of a nickel-plated material.
